(19) United States
(12) Patent Application Publication
(10) Pub. No.: US 2010/0055605 A1
(43) Pub. Date: Mar. 4, 2010

(54) PRINTED CIRCUIT BOARD AND METHOD OF MANUFACTURING THE SAME

(75) Inventors: Shang-Hoon SEO, Seoul (KR); Jae-Woo Joung, Suwon-si (KR); Kyoung-Jin Jeong, Suwon-si (KR); Kwan-Soo Yun, Suwon-si (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/435,002

(22) Filed: May 4, 2009

(30) Foreign Application Priority Data
Aug. 28, 2008 (KR) 10-2008-0084596

(51) Int. Cl. G03F 7/004; G03F 7/20

(52) U.S. Cl. 430/270.1; 430/319

(57) ABSTRACT

A printed circuit board and a method of manufacturing the printed circuit board are disclosed. The method of manufacturing the printed circuit board in accordance with an embodiment of the present invention can include: forming an opaque conductive pattern on one side of a transparent insulation layer; forming a photosensitive insulation layer on the transparent insulation layer such that the conductive pattern is covered; hardening the photosensitive insulation layer excluding an area covering the conductive pattern by irradiating light on the other side of the transparent insulation layer; and forming an opening on the photosensitive insulation layer by removing the area of the photosensitive insulation layer covering the conductive pattern such that the conductive pattern is exposed.

### CROSS-REFERENCE TO RELATED APPLICATIONS

This application claims the benefit of Korean Patent Application No. 10-2008-0084596, filed with the Korean Intellectual Property Office on Aug. 28, 2008, the disclosure of which is incorporated herein by reference in its entirety.

### BACKGROUND

1. Technical Field

The present invention relates to a printed circuit board and a method of manufacturing the printed circuit board.

2. Description of the Related Art

Printed circuit board (PCB) is a basic component of electronic products for a variety of applications. Not only is the PCB used for mobile phones, laptop computers and camcorders, but also it is used as a board for a semiconductor package such as a ball grid array board, a chip scale package and a multi chip module.

According to the related art, after forming an etching resist on a copper foil film of a copper clad laminate and then exposing and developing a certain portion of the etching resist using a mask, a circuit pattern and a pad may be formed by etching the copper foil film. Then, a solder resist may be formed on an insulation layer of the copper clad laminate such that the circuit pattern and the pad may be covered, and then the pad may be exposed by using a mask through the exposing and developing processes, for follow-up processes such as wire bonding and soldering.

However, in case these conventional technologies are followed, there may be several problems to be solved. Firstly, while forming a circuit pattern and a pad, the whole process may become complicated due to the performing of the exposing and developing processes, thereby increasing manufacturing time and production costs. Secondly, due to an additional cost needed to make a mask for each process, the overall manufacturing costs may be increased.

### SUMMARY

The present invention provides a printed circuit board and a method of manufacturing the printed circuit board in which the manufacturing time can be shortened and the manufacturing costs can be reduced by simplifying the process.

An aspect of the present invention provides a method of manufacturing a printed circuit board. The method of manufacturing the printed circuit board in accordance with an embodiment of the present invention can include: forming an opaque conductive pattern on one side of a transparent insulation layer; forming a photosensitive insulation layer on the transparent insulation layer such that the conductive pattern is covered; hardening the photosensitive insulation layer excluding an area covering the conductive pattern by irradiating light on the other side of the transparent insulation layer; and forming an opening on the photosensitive insulation layer by removing the area of the photosensitive insulation layer covering the conductive pattern such that the conductive pattern is exposed.

In this case, the transparent insulation layer can be made of a material including a photosensitive material, and the hardening of the photosensitive insulation layer can include hardening the photosensitive insulation layer and the transparent insulation layer collectively in a single process.

Moreover, the method can further include, before the forming of the conductive pattern, forming the transparent insulation layer by coating transparent insulation ink through inkjet printing.

The conductive pattern can be made of a material including a photosensitive material, and the hardening of the photosensitive insulation layer can include hardening the photosensitive insulation layer and the conductive pattern collectively in a single process.

The forming of the conductive pattern can be performed by coating conductive ink on one side of the transparent insulation layer through inkjet printing.

The forming of the photosensitive insulation layer can be performed by coating photosensitive insulation ink on the transparent insulation layer through inkjet printing.

Another aspect of the present invention provides a printed circuit board. The printed circuit board in accordance with an embodiment of the present invention can include: a transparent insulation layer; an opaque conductive pattern configured to be formed on one side of the transparent insulation layer; and a photosensitive insulation layer configured to be formed on the transparent insulation layer, in which an opening is formed on the photosensitive insulation layer such that the conductive pattern is exposed.

The transparent insulation layer can be made of a material including a photosensitive material.

The conductive pattern can be made of a material including a photosensitive material.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a flow chart illustrating a method of manufacturing a printed circuit board in accordance with an embodiment of the present invention.

FIGS. 2 to 7 are cross sectional views illustrating a method of manufacturing a printed circuit board in accordance with an embodiment of the present invention.

FIGS. 8 to 13 are plan views illustrating a method of manufacturing a printed circuit board in accordance with an embodiment of the present invention.

FIG. 14 is a cross sectional view illustrating a printed circuit board in accordance with another embodiment of the present invention.

FIG. 15 is a plan view illustrating a printed circuit board in accordance with another embodiment of the present invention.

### DETAILED DESCRIPTION

In accordance with certain embodiments of the present invention, a printed circuit board and a method of manufacturing the printed circuit board will be described below in more detail with reference to the accompanying drawings. Those components that are the same or are in correspondence are rendered the same reference numeral regardless of the figure number, and redundant explanations are omitted.

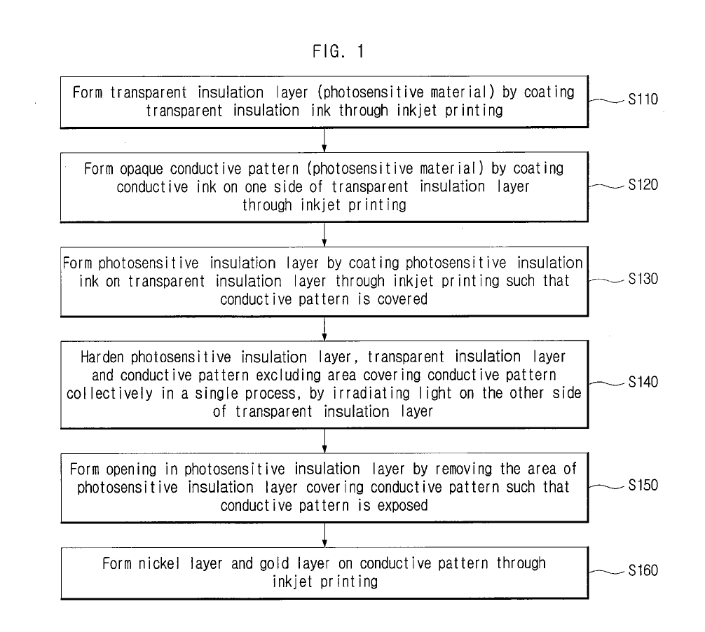

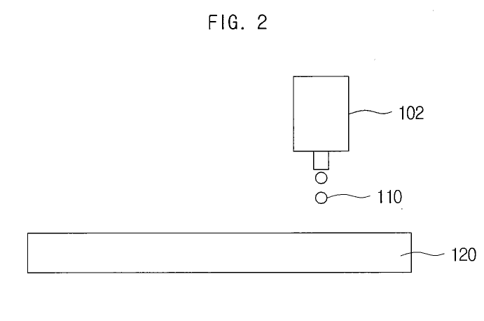

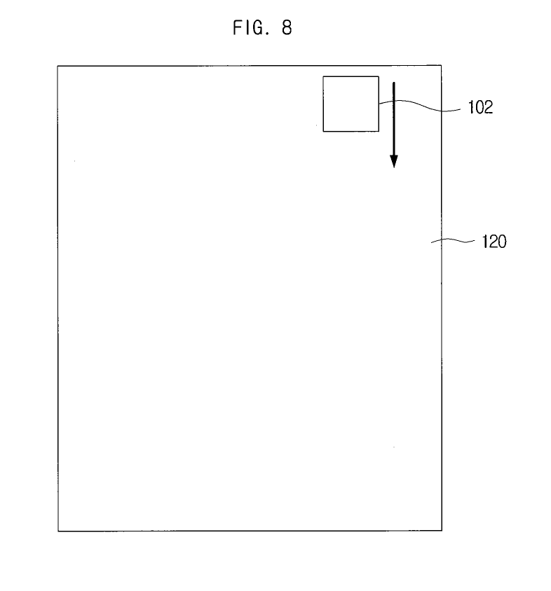

FIG. 1 is a flow chart illustrating a method of manufacturing a printed circuit board 100 in accordance with an embodiment of the present invention. FIGS. 2 to 7 are cross sectional views illustrating a method of manufacturing the printed circuit board 100 in accordance with an embodiment of the present invention. FIGS. 8 to 13 are plan views illustrating a method of manufacturing the printed circuit board 100 in accordance with an embodiment of the present invention.

Illustrated in FIGS. 2 to 13 is a method of manufacturing the printed circuit board 100 in accordance with an embodiment of the present invention that includes: forming an opaque conductive pattern 140 on one side of a transparent insulation layer 120; forming a photosensitive insulation layer 160 on the transparent insulation layer 120 to cover the conductive pattern 140; hardening the photosensitive insulation layer 160 excluding the area covering the conductive pattern 140 by irradiating light on the other side of the transparent insulation layer 120; and forming an opening 162 on the photosensitive insulation layer 160 by removing the area of the photosensitive insulation layer 160 covering the conductive pattern 140 such that the conductive pattern 140 is exposed.

By comparison with the related art, in which a circuit pattern and a pad are formed by way of etching after the exposing and developing processes according to the photolithography and subtractive methods, the present embodiment can simplify the processes by omitting the exposing and developing processes, thereby reducing the manufacturing time and costs, and does not require any additional cost since there is no need to have a mask for forming the opening 162 on the photosensitive insulation layer 160.

Each of the processes will be described in more detail hereinafter.

First, as illustrated in FIGS. 2 and 8, a transparent insulation layer 120 is formed by coating transparent insulation ink 110 through inkjet printing (S110). In other words, the transparent layer 120 is formed on a supporting board (not shown) by coating the transparent insulation ink 110 through the use of an inkjet head 102.

In this case, the transparent insulation ink 110 and the transparent layer 120, which is formed from the transparent insulation ink 110, are made of a photosensitive material and thus can be hardened by irradiating light, for example, ultraviolet rays, in a following process.

Here, if the transparent insulation ink 110 is in a liquid state through heating, the transparent insulation ink 110 can be cooled and dried as it hits the supporting board (not shown). If the transparent insulation ink 110 stays in the liquid state at room temperature, it can be dried by irradiating relatively weak energy.

Through this drying, the transparent insulation layer 120 becomes more viscous enough to allow the conductive pattern 140 and the photosensitive insulation layer 160 to form on the transparent insulation layer 120. As a result, although the transparent insulation layer 120 is not yet hardened, it is possible to form the conductive pattern 140 by coating conductive ink 130 on the transparent insulation layer 120 and form the photosensitive insulation layer 160 on the transparent insulation layer 120 by coating photosensitive insulation ink 150.

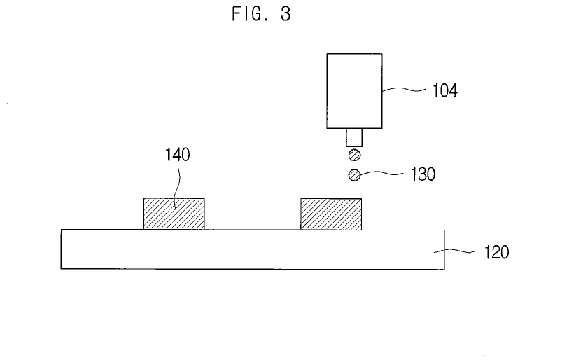

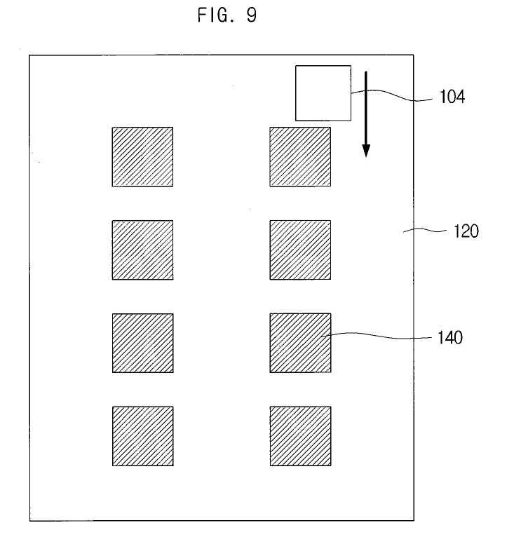

Next, as illustrated in FIGS. 3 and 9, the opaque, conductive pattern 140 is formed on one side of the transparent insulation layer 120 by coating the conductive ink 130 (S120). In other words, by coating the conductive ink 130 on one side of the transparent insulation layer 120, which is in a dried state as described above, by using an inkjet head 104, the opaque, conductive pattern 140, for example, a pad, can be formed more finely.

In addition, by directly printing the conductive pattern 140 on the transparent insulation layer 120 through inkjet printing, the present embodiment can omit the exposing and developing processes, thereby reducing the manufacturing time and costs, in comparison with the related art, in which a circuit pattern is formed through the photolithography and subtractive methods.

In this case, the conductive ink 130 and the conductive pattern 140, which is formed from the conductive ink 130, are made of a photosensitive material, like the transparent insulation layer 120, and thus can be hardened by irradiating light, for example, ultraviolet rays, in a following process.

If the conductive ink 130, like the transparent insulation ink 110 described above, is in a liquid state through heating, the conductive ink 130 can be cooled and dried as it hits the transparent insulation layer 120. If the conductive ink 130 stays in the liquid state at room temperature, it can be dried by irradiating relatively weak energy.

Through this drying, the conductive pattern 140 becomes more viscous enough to allow the photosensitive insulation layer 160 to form on the conductive pattern 140. As a result, although the conductive pattern 140 is not yet hardened, it is possible to form the photosensitive insulation layer 160 by coating the photosensitive insulation ink 150 on the transparent insulation layer 120 to cover the conductive pattern 140.

The conductive pattern 140 formed through the above process can function as a mask, which is for forming an opening 162 by removing a portion of the photosensitive insulation layer 160, and thus this will be described later in more detail when the photosensitive insulation layer 160, the transparent insulation layer 120 and the conductive pattern 140 are described.

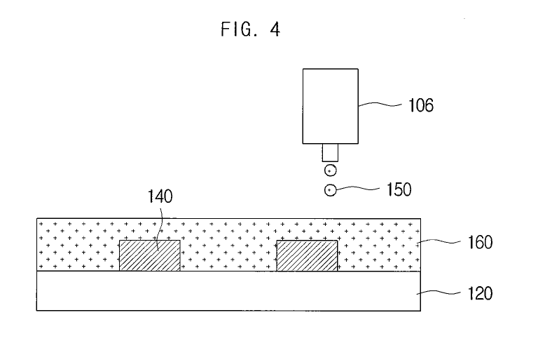

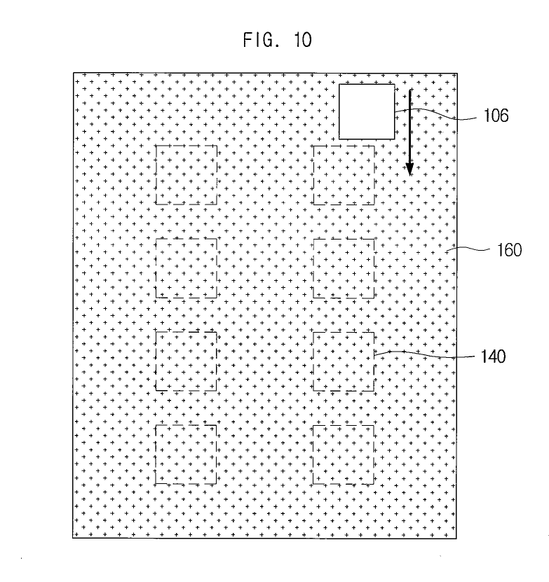

Next, as illustrated in FIGS. 4 and 10, the photosensitive insulation layer 160 is formed on the transparent insulation layer 120 by coating the photosensitive insulation ink 150 through inkjet printing to cover the conductive pattern 140 (S130). That is, the photosensitive insulation layer 160, for example, solder resist, is formed by coating the photosensitive insulation ink 150 on the transparent insulation layer 120 such that the conductive pattern 140 is completely covered by using an inkjet head 106.

Like the above transparent insulation layer 120 and conductive pattern 140, the photosensitive insulation layer 160 can be dried even before the hardening, when the photosensitive insulation layer 160 is in a liquid state by heating or at a normal temperature.

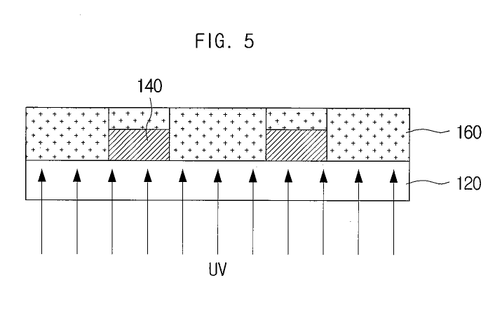

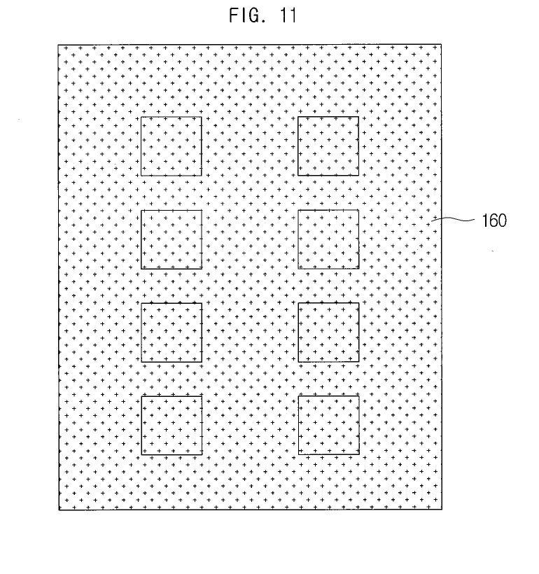

Next, as illustrated in FIGS. 5 and 11, the photosensitive insulation layer 160, transparent insulation layer 120 and conductive pattern 140 excluding the area of covering the conductive pattern 140 are hardened collectively in a single process by irradiating light on the other side of the transparent insulation layer 120.

When irradiating light, for example, ultraviolet rays, on the other side of the transparent insulation layer 120, the area of the photosensitive insulation layer 160 covering the conductive pattern 140 cannot receive the light because the conductive pattern 140 is opaque and thus functions as a mask. As a result, the area of the photosensitive insulation layer 160 not having received any light cannot be hardened, and only the remaining area is hardened by receiving the light passing through the transparent insulation layer 120.

As described above, since the transparent insulation layer 120 and the conductive pattern 140 are made of photosensitive materials and thus can be also hardened during the hardening process of the photosensitive insulation layer 160. That is, the transparent insulation layer 120 and the conductive pattern 140 in a dry state are not hardened through a separate hardening process, but the transparent insulation layer 120 and the conductive pattern 140 are collectively hardened during the hardening process, the manufacturing process of the photosensitive layer 160, simplifying the process and reducing the production time and costs.

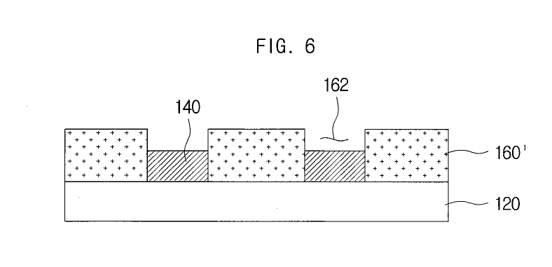

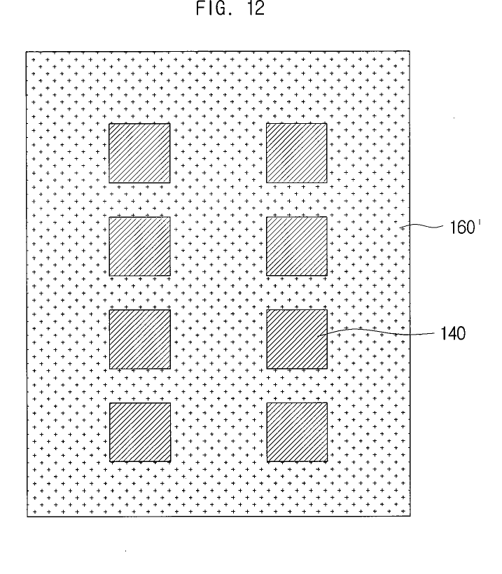

Next, as illustrated in FIGS. 6 and 12, the opening 162 is formed on the photosensitive insulation layer 160 by removing the area of the photosensitive insulation layer 160 covering the conductive pattern 140 such that the conductive pattern 140 is exposed (S150). As described above, by removing a certain area of the photosensitive insulation layer 160 covering the conductive pattern 140 that is not hardened by the conductive pattern 140 functioning as a mask, the photosensitive insulation layer 160 having the opening 162 formed therein to expose the conductive pattern 140 is formed.

As such, since there is no additional mask, for example, a pad, needed for exposing the conductive pattern 140, the manufacturing costs for such a mask can be reduced, and there is also no additional process or equipment needed for disposing and arranging a mask, thereby reducing the overall manufacturing time and costs.

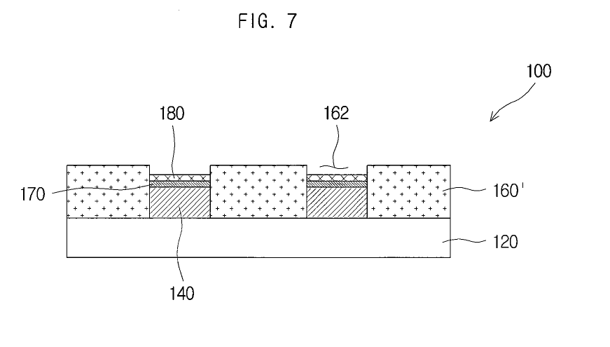

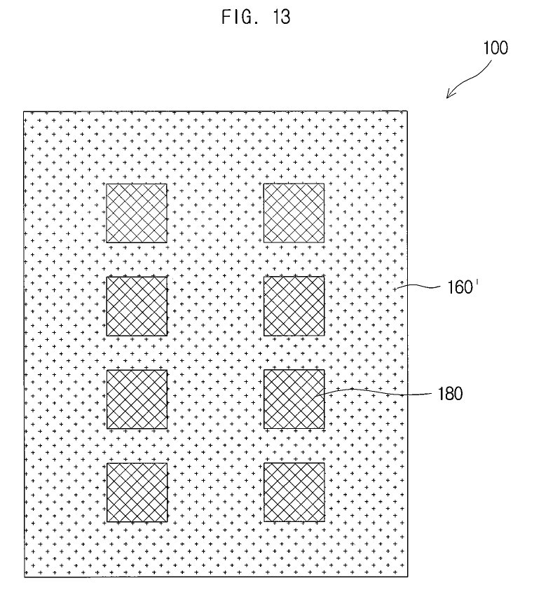

Next, as illustrated in FIGS. 7 and 13, a nickel layer 170 and a gold layer 180 are formed on the conductive pattern 140 by way of inkjet printing (S160). That is, for wire bonding or soldering, the nickel layer 170 is formed on the conductive pattern 140, for example, a pad, by way of inkjet printing, and then the gold layer 180 is sequentially formed on the nickel layer 170 by way of inkjet printing.

As such, by using the inkjet printing, the nickel layer 170 and the gold layer 180 can be formed more simply and precisely.

As described above, by performing the whole process of forming the transparent insulation layer 120, the conductive pattern 140, the photosensitive insulation layer 160, the nickel layer 170, and the gold layer 180 through the inkjet printing, the whole process can be simplified in comparison with the conventional photolithography and subtractive processes.

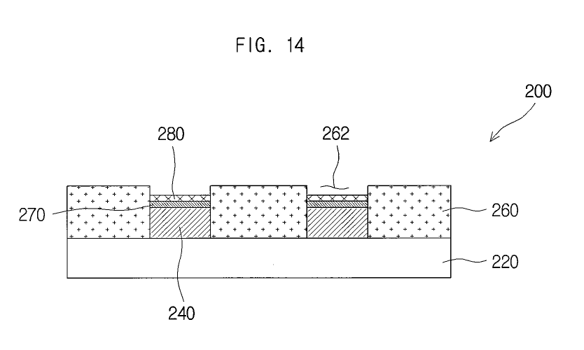

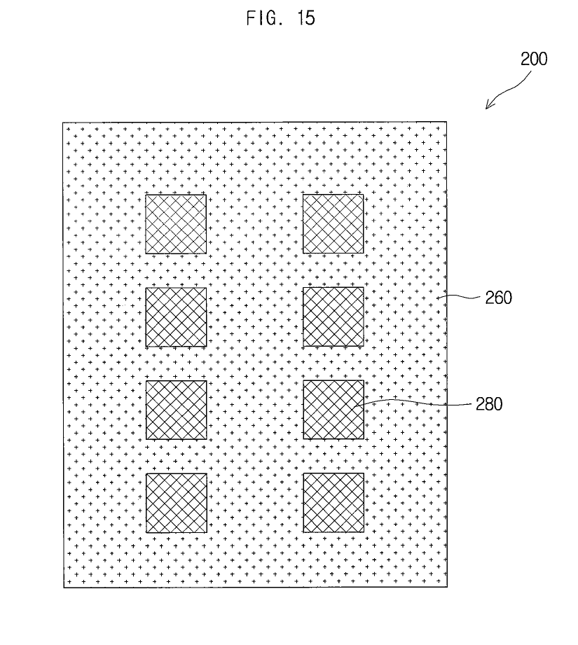

Next, a printed circuit board 200 according to another embodiment of the present invention will be described by referring to FIGS. 14 and 15.

FIG. 14 is a cross sectional view illustrating a printed circuit board 200 in accordance with another embodiment of the present invention. FIG. 15 is a plan view illustrating the printed circuit board 200 in accordance with another embodiment of the present invention.

Illustrated in FIGS. 14 and 15 is the printed circuit board 200 in accordance with the present embodiment, which includes: a transparent insulation layer 220; an opaque conductive pattern 240, which is formed on one side of the transparent insulation layer 220; and a photosensitive insulation layer 260, which is formed on the transparent insulation layer 220 and has an opening 262 being formed in the photosensitive insulation layer 260 such that the conductive pattern 240 is exposed.

In accordance with the present embodiment, by comparison with the related art, in which a circuit pattern and a pad is formed by way of etching after the exposing and developing processes according to the photolithography and subtractive methods, the present embodiment can simplify its processes by omitting the exposing and developing processes, thereby implementing the printed circuit board 200 reducing manufacturing time and costs. In addition, when manufacturing, there is no additional cost needed to make a mask.

Below, each component will be described in more detail.

The conductive pattern 240 and the photosensitive insulation layer 260 are formed on one side of the transparent insulation layer 220. Such transparent insulation layer 220 can be formed on a supporting board (not shown) by coating transparent insulation ink through the inkjet printing method, and the method of manufacturing the printed circuit board is substantially the same as or similar to that of the embodiment described earlier and thus will not be described again.

The transparent insulation layer 220 can be made of a photosensitive material. As such, the transparent insulation layer 220 can be hardened by irradiating light, for example, ultraviolet rays, and such hardening process can be simultaneously performed during the hardening of the photosensitive insulation layer 260, thereby implementing the printed circuit board 200 in a simplified manufacturing process.

The conductive pattern 240 can be formed on one side of the transparent insulation layer 220 and made of an opaque material. Such conductive pattern 240 can be also formed on the transparent insulation layer 220 by coating conductive ink through the inkjet printing method, and the method of manufacturing the printed circuit board is substantially the same as or similar to that of the embodiment described earlier and thus will not be described again.

Like the transparent insulation layer 220, the conductive pattern 240 can be made of a photosensitive material. As such, it can be also hardened by irradiating light, for example, ultraviolet rays, and such hardening process can be simultaneously performed during the hardening of the photosensitive insulation layer 260, thereby implementing the printed circuit board 200 in a simplified manufacturing process.

Such conductive pattern 240 can be performed as a mask for removing a portion of the photosensitive insulation layer 260. In other words, the conductive pattern 240 and the photosensitive insulation layer 260 are formed on one side of the transparent insulation layer 220, and since the transparent insulation layer 220 is transparent, the light having passed through the transparent insulation layer 220 cannot pass through the opaque conductive pattern 240 when irradiating light such as ultraviolet rays on the other side of the transparent insulation layer 220. Therefore, the area of the photosensitive insulation layer 260 covering the conductive pattern 240 cannot be hardened and thus can be removed.

As such, since there is no additional mask needed to form the opening 262 for exposing the conductive pattern 240, for example, a pad, on the photosensitive insulation layer 260, manufacturing costs of such mask can be saved, and there is also no additional process and equipment needed for disposing and arranging a mask, thereby implementing the printed circuit board 200 at reduced manufacturing time and costs.

The photosensitive insulation layer 260 is formed on the transparent insulation layer 220, and has the opening 262 formed therein to expose the conductive pattern 240. After forming the photosensitive insulation layer 160 (in FIG. 4) by coating the photosensitive insulation ink on the transparent insulation layer 220 through the inkjet printing method such that the conductive pattern 240 is covered, the photosensitive insulation layer 260 can be formed, as described above, by removing the area covering the conductive pattern 140 and forming the opening 262 in the transparent insulation layer 220.

In other words, when forming the opening 262 in the photosensitive insulation layer 160 (in FIG. 4), as the conductive pattern 240, for example, a pad, itself functions as a mask, a portion of the photosensitive insulation layer 160 (in FIG. 4) covering the conductive pattern 240 cannot be hardened since it cannot receive any light being incident from the other side of the transparent insulation layer 220 and thus can be removed. Here, the method of manufacturing the printed circuit board is substantially the same as or similar to that of the embodiment described earlier and thus will not be described again.

A nickel layer 270 and a gold layer 280 are successively formed on the conductive pattern 240, for example, a pad. For wire bonding or soldering, the nickel layer 270 is formed on the exposed conductive pattern 240, and then the gold layer 280 is formed on the nickel layer 270.

Such nickel layer 270 and gold layer 280 can be also formed by way of inkjet printing, thereby simplifying the manufacturing process and realizing the printed circuit board 200 with improved precision.

As described above, by performing the whole process of forming the transparent insulation layer 220, the conductive pattern 240, the photosensitive insulation layer 260, the nickel layer 270, and the gold layer 280 through the inkjet printing, the printed circuit board 200, of which the process is simplified in comparison with the conventional photolithography and subtractive processes, can be realized.

According to the embodiments of the present invention as set forth above, the manufacturing time and costs can be reduced by simplifying the manufacturing process, and there is no need for a mask so that the cost for making a mask can be saved.

While the spirit of the invention has been described in detail with reference to certain embodiments, the embodiments are for illustrative purposes only and do not limit the invention. It is to be appreciated that those skilled in the art can change or modify the embodiments without departing from the scope and spirit of the invention. As such, many embodiments other than those set forth above can be found in the appended claims.

What is claimed is:

1. A method of manufacturing a printed circuit board, the method comprising:
forming an opaque conductive pattern on one side of a transparent insulation layer;
forming a photosensitive insulation layer on the transparent insulation layer such that the conductive pattern is covered;
hardening the photosensitive insulation layer excluding an area covering the conductive pattern by irradiating light on the other side of the transparent insulation layer; and
forming an opening on the photosensitive insulation layer by removing the area of the photosensitive insulation layer covering the conductive pattern such that the conductive pattern is exposed.

2. The method of claim 1, wherein the transparent insulation layer is made of a material including a photosensitive material and the hardening of the photosensitive insulation layer comprises hardening the photosensitive insulation layer and the transparent insulation layer collectively in a single process.

3. The method of claim 2, further comprising, before the forming of the conductive pattern, forming the transparent insulation layer by coating transparent insulation ink through inkjet printing.

4. The method of claim 1, wherein the conductive pattern is made of a material including a photosensitive material and the hardening of the photosensitive insulation layer comprises hardening the photosensitive insulation layer and the conductive pattern collectively in a single process.

5. The method of claim 4, wherein the forming of the conductive pattern is performed by coating conductive ink on one side of the transparent insulation layer through inkjet printing.

6. The method of claim 1, wherein the forming of the photosensitive insulation layer is performed by coating photosensitive insulation ink on the transparent insulation layer through inkjet printing.

7. A printed circuit board comprising:
a transparent insulation layer;
an opaque conductive pattern configured to be formed on one side of the transparent insulation layer; and
a photosensitive insulation layer configured to be formed on the transparent insulation layer, an opening configured to be formed on the photosensitive insulation layer such that the conductive pattern is exposed.

8. The printed circuit board of claim 7, wherein the transparent insulation layer is made of a material including a photosensitive material.

9. The printed circuit board of claim 7, wherein the conductive pattern is made of a material including a photosensitive material.
